(19) United States
(12) Patent Application Publication
(10) Pub. No.: US 2013/0193301 A1
(43) Pub. Date: Aug. 1, 2013

(54) SOLAR PANEL ATTACHMENT SYSTEM FOR A ROOF

(71) Applicants: Nicholas Jackson, Davisburg, MI (US); Todd L. Hemingway, Metamora, MI (US); Todd Murray, Gaines, MI (US)

(72) Inventors: Nicholas Jackson, Davisburg, MI (US); Todd L. Hemingway, Metamora, MI (US); Todd Murray, Gaines, MI (US)

(73) Assignee: A. RAYMOND ET CIE, Grenoble (FR)

(21) Appl. No.: 13/360,770

(22) Filed: Jan. 29, 2012

(51) Int. Cl. F16M 11/00; H01L 31/18

(52) U.S. Cl. 248/676; 29/890.033

(57) ABSTRACT

An attachment system is provided. In another aspect, an elongated member is inserted through support assembly to secure the support assembly to a building roof. Another aspect employs a bracket having a guide pin that engages a pin receptacle on a stand as the bracket is lowered onto the stand. A method of attaching a solar panel to a building is additionally provided.

### BACKGROUND AND SUMMARY

The present application relates generally to an attachment system and more particularly to a solar panel attachment system for a roof of a building.

Conventional photovoltaic or solar panels are mounted to roofs of buildings through screw-in clips or the like. Examples of such conventional devices are disclosed in U.S. Patent Publication No. 2011/0088740 entitled “Photovoltaic Panel Clamp” which published to Mittan et al. on Apr. 21, 2011, and U.S. Pat. No. 6,672,018 entitled “Solar Module Mounting Method and Clip” which issued to Shingleton on Jan. 6, 2004, both of which are incorporated by reference herein. Such conventional methods cause the installer to juggle many loose fasteners while simultaneously holding heavy solar panels and/or roof mounting components, often on a tilted metal roof in unpleasant weather conditions. Furthermore, such traditional multi-piece screw or bolt arrangements take considerable time to install while also having inconsistent installation torque values, especially in the common situation where many of these solar panel mounting devices are required for each roof.

In accordance with the present invention, an attachment system is provided. In another aspect, an elongated member is inserted through support assembly to secure the support assembly to a building roof. Another aspect employs a bracket having a guide pin that engages a pin receptacle on a stand as the bracket is lowered onto the stand. A method of attaching a solar panel to a building is additionally provided.

The present attachment system is advantageous over traditional devices. For example, in one aspect, an elongated member is inserted through a support assembly to secure a solar panel to a building roof without piercing the building roof. In an aspect of the present attachment system, a solar panel is quickly and easily secured to a building roof in a fast manner without requiring an installer to juggle multiple parts. In another aspect, a bracket is preassembled directly to a glass surface of a solar panel and a stand is secured to a building roof via an elongated member, prior to assembly of the bracket to the stand. Moreover, the solar panel is easily disassembled from a portion of a support assembly in an aspect of the present system. In another aspect, a bracket is preassembled to a solar panel and a guide pin on the bracket engages a pin receptacle on a stand to position the solar panel as the solar panel is lowered onto the stand. Another aspect involves a coupler that engages the guide pin when the guide pin is positioned in the pin receptacle to removably couple the bracket to the stand. Another aspect of the present system is advantageous over conventional devices since this aspect uses lightweight and strong plastic materials for various components of the attachment system. Additional advantages and features of the present invention will become apparent in the following description and appended claims, taking in conjunction with the accompanying drawings.

### BRIEF DESCRIPTION OF THE DRAWINGS

FIG. 1 is a perspective view showing a first preferred embodiment attachment system securing a solar panel to a building roof;

FIG. 2 is a perspective view showing a portion of the first preferred embodiment attachment system;

FIG. 3 is an exploded perspective view showing a portion of the first preferred embodiment attachment system;

FIG. 4 is a top view of a portion of the first preferred embodiment attachment system;

FIG. 5 is a cross-sectional view, taken along line 5-5 of FIG. 4, showing the first preferred embodiment attachment system;

FIG. 6 is a cross-sectional view, taken along line 6-6 of FIG. 4, showing the first preferred embodiment attachment system;

FIG. 7 is a perspective view showing a bracket assembly as an alternative to a bracket of the first preferred embodiment attachment system;

FIG. 8 is an exploded perspective view showing the bracket assembly;

FIG. 9 is a perspective view of a second preferred embodiment attachment system securing the solar panel to the building roof;

FIG. 10 is a perspective view showing a portion of the second preferred embodiment attachment system securing the solar panel;

FIG. 11 is an exploded perspective view showing a portion of the second preferred embodiment attachment system;

FIG. 12 is a top view of a portion of the second preferred embodiment attachment system;

FIG. 13 is a cross-sectional view, taken along line 13-13 of FIG. 12, showing the second preferred embodiment attachment system;

FIG. 14 is a cross-sectional view, taken along line 14-14 of FIG. 12, showing the second preferred embodiment attachment system; and

FIG. 15 is an exploded perspective view of a guide pin and a coupler of the second preferred embodiment attachment system.

### DETAILED DESCRIPTION

Example embodiments will now be described more fully with reference to the accompanying drawings.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

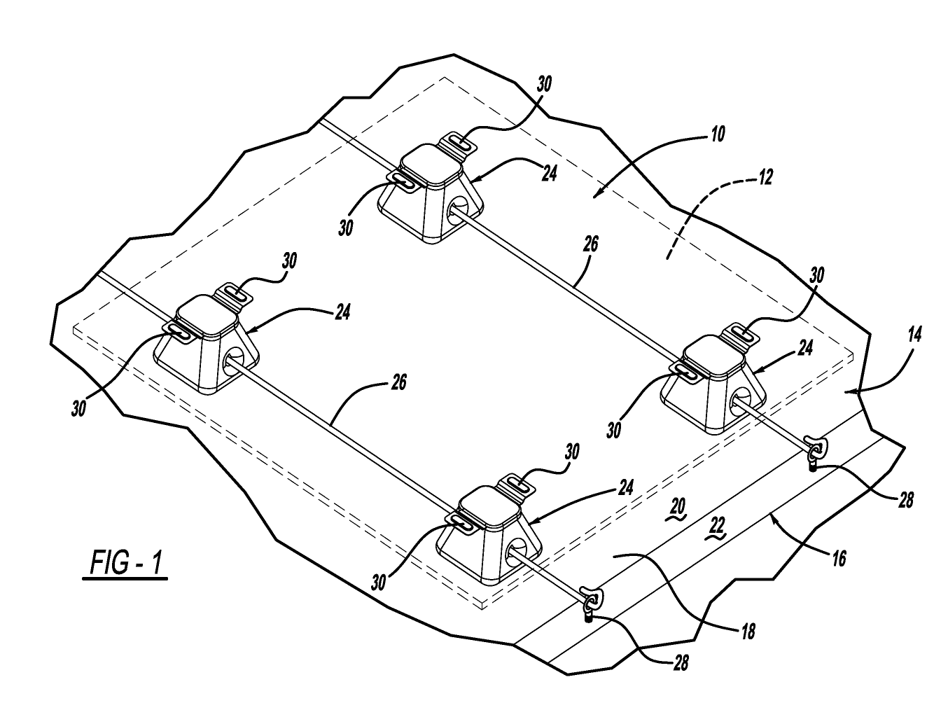

FIG. 1 illustrates a solar panel system 10 in accordance with the present invention. The solar panel system 10 includes a solar panel 12 and a solar panel attachment system 14 that mounts the solar panel 12 to a building 16. The building 16 includes a roof 18 having a first section 20 and a second section 22. The first section 20 of the roof 18 may be covered by a rubber membrane, and the second section 22 may be suitable for inserting fasteners therethrough. The solar panel attachment system 14 includes one or more support assemblies 24 that rest on the roof 18 and support the solar panel 12. One of the support assemblies 24 may be positioned adjacent to each corner of the solar panel 12, as shown.

Cables or wires 26 extend through the support assemblies 24 and secure the support assemblies 24 to the building 16. The wires 26 may be fixed to the second section 22 of the roof 18 using fasteners 28 such as eye bolts. Alternatively, the wires 26 may be fixed to another portion of the building 16, such as a wall. Although only one end of the wires 26 is shown, the other end of the wires 26 may be secured to the building 16 in a similar manner. The solar panel 12 is secured to the support assemblies 24 using an adhesive 30, such as Techbond® polyurethane adhesive (e.g., PUR 2 Max Tabs) obtained from A. Raybond Sarl.

The first section 20 may be covered by the rubber membrane to seal the first section 20 and thereby prevent the roof 18 from leaking. Conventional attachment systems mount solar panels to a roof of a building by driving a fastener into the roof and thereby piercing the roof. Piercing the first section 20 may cause water to penetrate the rubber membrane and, ultimately, cause leaks in the roof 18. In contrast, the solar panel attachment system 14 secures the solar panel 12 to the building 16 without piercing the first section 20, and thereby mounts the solar panel 12 without causing leaks in the roof 18.

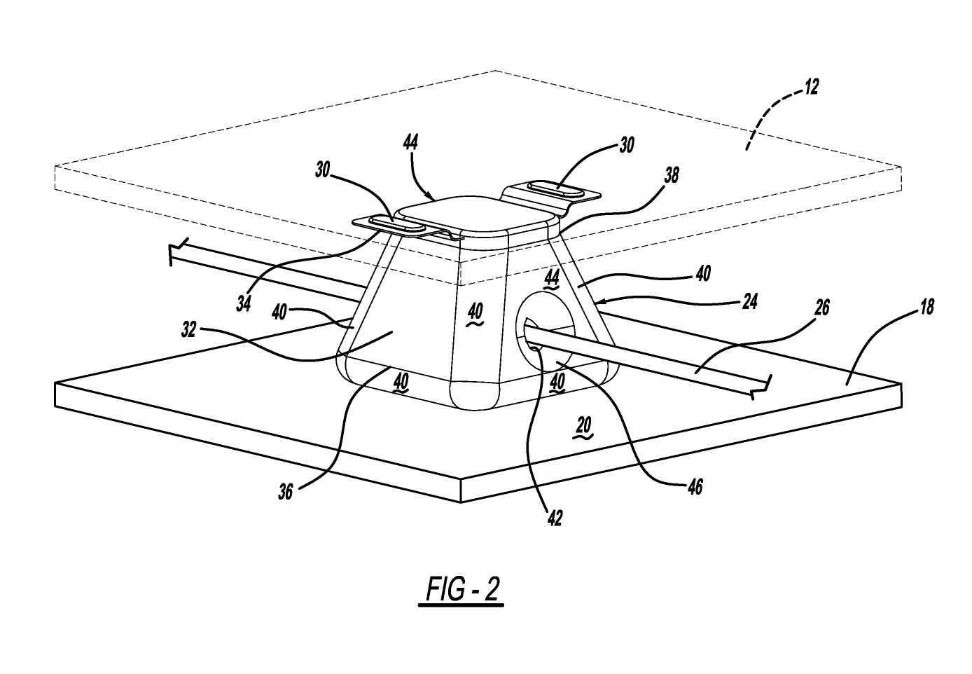

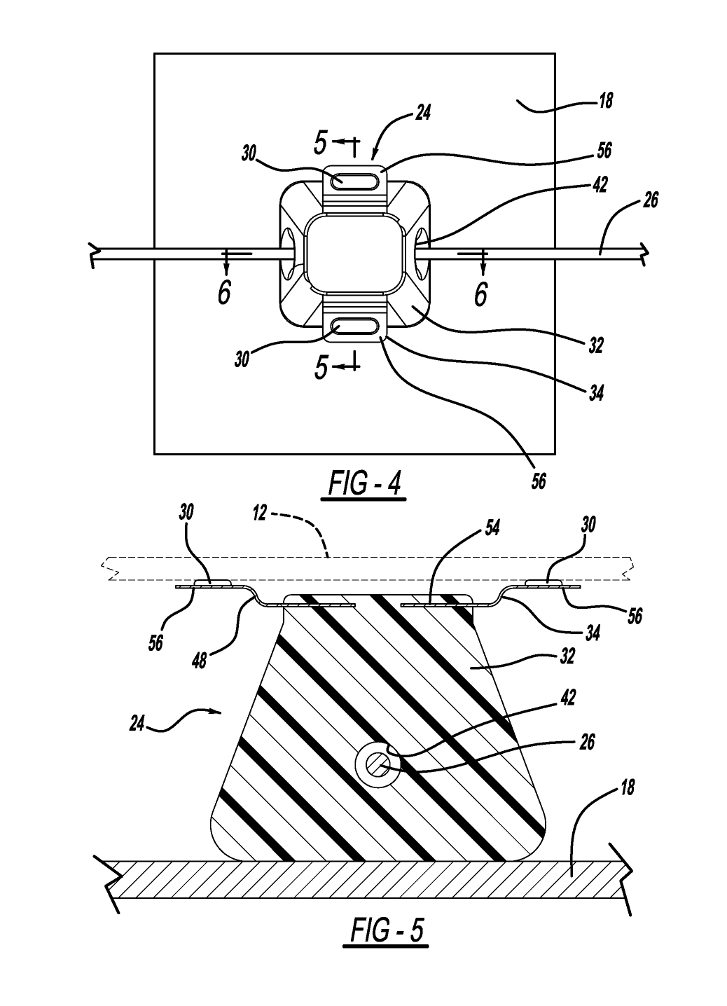

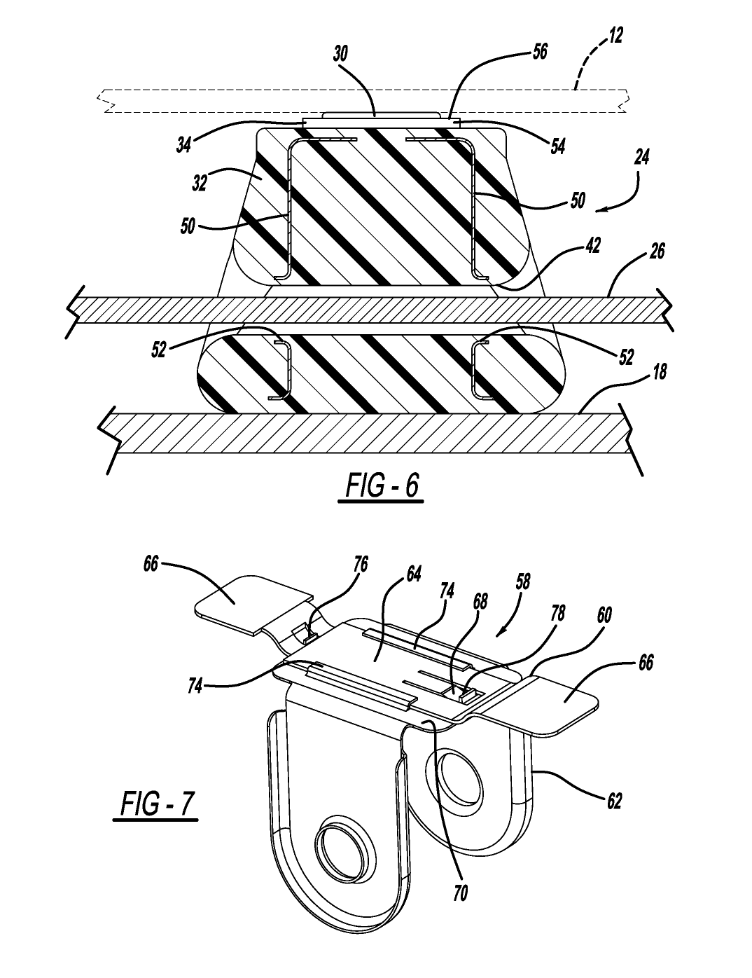

Referring now to FIGS. 2 through 6, each of the support assemblies 24 includes a stand 32 and a bracket 34. The stand 32 is formed from a permeated plastic, such as AR-Bag® plastic obtained from A. Raymond Group, which includes voids below the surface of the stand 32. The voids inhibit fracture propagation in the stand 32 and thereby improve the impact resistance of the stand 32. The bracket 34 is formed (e.g., stamped) from metal. The stand 32 may be overmolded (e.g., molded over the bracket 34), as shown. Alternatively, the stand 32 may be injection molded or vacuum formed and/or the bracket 34 may be assembled (e.g., fastened) to the stand 32.

As best shown in FIG. 2, the stand 32 has a base 36 and an apex 38 opposite from the base 36. The base 36 is wider than the apex 38 to distribute the load of the solar panel system 10 and thereby prevent leaks in the roof 18 caused by overloading the first section 20 of the roof 18. The apex 38 may be narrower than the base 36 to reduce material cost. The stand 32 may be a square frustum, as shown, or the stand 32 may have another suitable shape, such as a conical or rectangular frustum.

The stand 32 has edges 40 that are rounded to avoid piercing the roof 18 as the edges 40 contact the roof 18. The stand 32 defines a hole 42 that extends through opposite sidewalls 44 of the stand 32. The wires 26 are inserted through the hole 42 to secure the stand 32 to the roof 18. The hole 42 includes a guide portion 46 that guides the wires 26 into the hole 42. The guide portion 46 is tapered or funnel shaped.

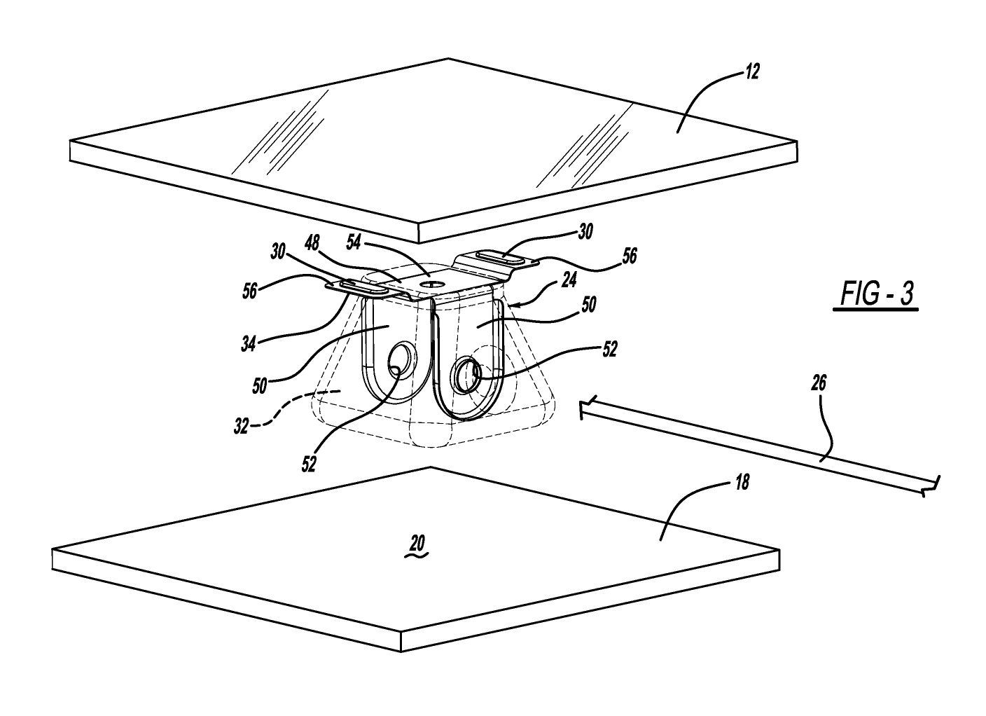

As best shown in FIG. 3, the bracket 34 has a yoke shape and includes a rectangular portion 48 and flanges 50 that extend downward from the rectangular portion 48. The flanges 50 define holes 52 that receive the wire 26. The wire 26 is routed through the hole 42 in the stand 32 (FIG. 2) and the holes 52 in the bracket 34 (FIG. 3) to secure the support assemblies 24 to the roof 18. In this regard, the bracket 34 reinforces the connection between the wire 26 and the stand 32. In addition, the stand 32 may be formed hollow or cored out to reduce material costs, in which case the hole 42 in the stand 32 would be divided into two holes. Thus, the holes 52 in the bracket 34 may help to guide the wire 26 from one of the holes in the stand 32 to the other one of the holes in the stand 32.

The rectangular portion 48 includes a generally flat portion 54 and pads 56 that are raised relative to the flat portion 54. The adhesive 30 is applied to the pads 56 to secure the solar panel 12 to each of the support assemblies 24. The pads 56 may be raised relative to the flat portion 54 by an amount that ensures the solar panel 12 does not contact the top surface of the stand 32 when the solar panel 12 is resting on the pads 56.

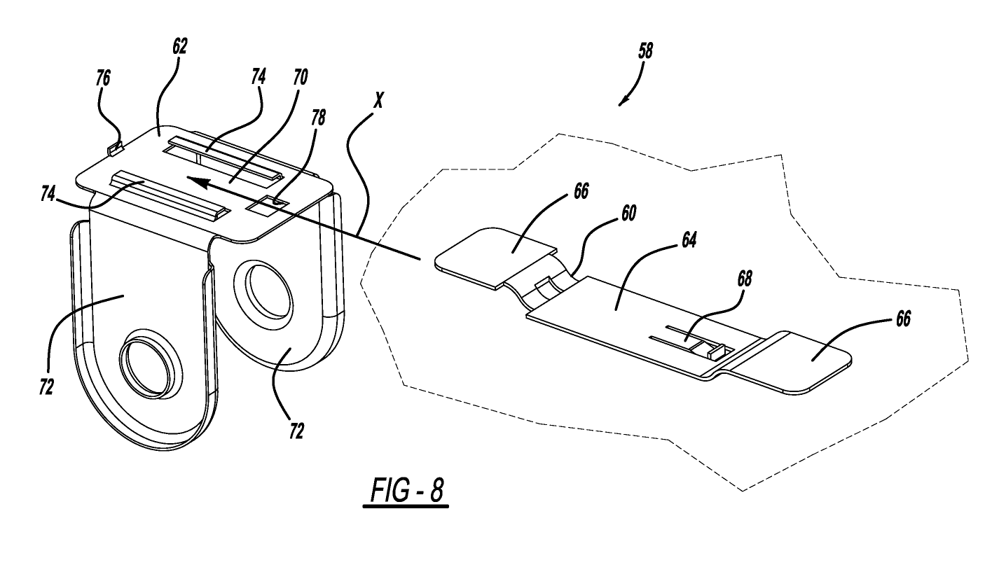

Referring now to FIGS. 7 and 8, a bracket assembly 58 in accordance with the present invention may be used in place of the bracket 34. The bracket assembly 58 includes a first bracket 60 and a second bracket 62. The first bracket 60 has a generally rectangular shape and the second bracket 62 has a yoke shape. The first bracket 60 and the second bracket 62 are formed (e.g., stamped) from metal.

The first bracket 60 includes a generally flat portion 64, pads 66 that are raised relative to the flat portion 64, and a flexible arm 68 extending from the flat portion 64. The second bracket 62 includes a generally flat portion 70 and flanges 72 extending downward from the flat portion 70, along with guide rails 74 and a tab 76 extending upward from the flat portion 70. In addition, the guide rails 74 extend laterally inward from the flat portion 70, and a slot 78 extends through the flat portion 70.

The stand 32 may be molded over the second bracket 62, the first bracket 60 may be preassembled to the solar panel 12 using the adhesive 30, and the first bracket 60 may be coupled to the second bracket 62 using a tongue-and-groove connection. In this regard, the first bracket 60 may be slid in a direction X until the first bracket 60 abuts the tab 76 on the second bracket 62. In turn, the guide rails 74 extend over the flat portion 64 of the first bracket 60 to secure the solar panel 12 to the building 16. In addition, the flexible arm 68 on the first bracket 60 snaps into the slot 78 in the second bracket 62 to prevent the first bracket 60 from sliding in a direction that is opposite from the direction X. The solar panel 12 may be removed by pushing up on the flexible arm 68 and sliding the first bracket 60 in the direction that is opposite from the direction X.

Alternatively, the solar panel 12 may be secured to the building 16 using a snap-fit connection. The snap-fit connection enables preassembling a portion of the support assemblies 24 to the solar panel 12 and lowering the preassembled components onto the remainder of the support assemblies 24 to secure the solar panel 12 to the building 16. For example, the guide rails 74 may be flexible so that, as the first bracket 60 is lowered between the guide rails 74, the guide rails 74 flex laterally outward and then snap back over the first bracket 60. The solar panel 12 may then be removed by spreading apart the guide rails 74 and lifting up the solar panel 12.

In another example, the first bracket 60 may include a first latch that extends downward from the flat portion 64 of the first bracket 60 and the stand 32 may include a second latch that extends upward from the stand 32.

The ends of the latches may include hook features that engage one another as the first latch is slid over the second latch. In addition, the first latch may extend laterally inward from the flat portion 64 to ensure that the first latch slides past and engages the second latch as the solar panel 12 is lowered onto the stand 32. Thus, using either the tongue-and-groove connection or the snap-fit connection, the solar panel 12 may be disassembled for maintenance purposes.

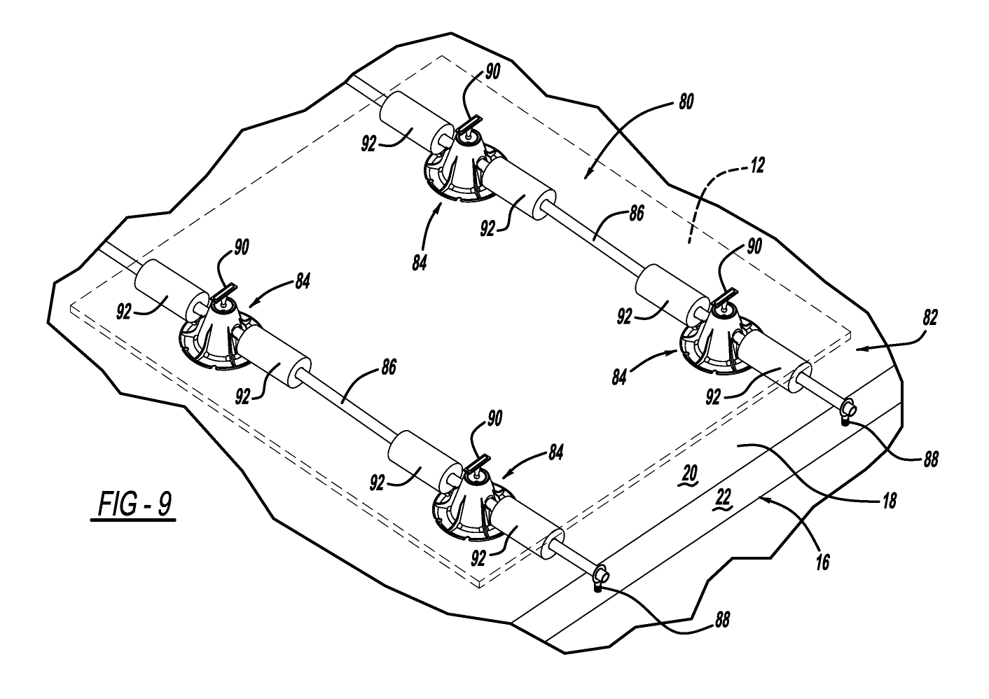

FIG. 9 illustrates a solar panel system 80 in accordance with the present invention mounted to the building 16. The solar panel system 80 includes the solar panel 12 and a solar panel attachment system 82 that mounts the solar panel 12 to the building 16. The solar panel attachment system 82 includes one or more support assemblies 84 that rest on the roof 18 of the building 16 and support the solar panel 12. One of the support assemblies 84 may be positioned adjacent to each corner of the solar panel 12, as shown.

Tubes or pipes 86 are routed through the support assemblies 84 to secure the support assemblies 84 to the building 16. The pipes 86 may be fixed to the second section 22 of the roof 18 using fasteners 88 such as eye bolts. Alternatively, the support assemblies 84 may be fixed to another portion of the building 16, such as a wall. Although only one end of the pipes 86 is shown, the other end of the pipes 86 may be secured to the building 16 in a similar manner. Thus, the solar panel attachment system 82 secures the solar panel 12 to the building 16 without piercing the first section 20, and thereby mounts the solar panel 12 without causing leaks in the roof 18. The solar panel 12 is secured to the support assemblies 84 using an adhesive 90, such as Techbond® polyurethane adhesive (e.g., PUR 2 Max Tabs) obtained from A. Raybond Sarl.

Weights 92 are slid onto the pipes 86 on opposite sides of the support assemblies 84 to prevent the support assemblies 84 from lifting off the roof 18 due to, for example, high winds. The weights 92 may be cylinders formed from cement or recycled rubber. The pipes 86 and the weights 92 may be standard sizes that are already available in, for example, local markets throughout the United States, and therefore do need to be specially made. To aid in positioning the support assemblies 84 on the pipes 86, holes (not shown) may be formed in the pipes 86 and the support assemblies 84 may include a snap fit mechanism (not shown) that snaps into the holes when the support assemblies 84 reach a certain position.

Conventional attachment systems place weights, such as cylinder blocks, on the edges of support assemblies so that part of the weights are resting on the support assemblies and part of the weights are resting on the roof 18. Placing weights on the support assemblies 84 in this manner may obstruct water flow on the roof 18, causing water (or ice) to puddle at or near the support assemblies 84 and possibly causing leaks in the roof 18. In contrast, the solar panel attachment system 82 maintains the weights 92 above the roof 18 so that the weights 92 do not obstruct water flow on the roof 18, and therefore the weights 92 do not cause leaks in the roof 18.

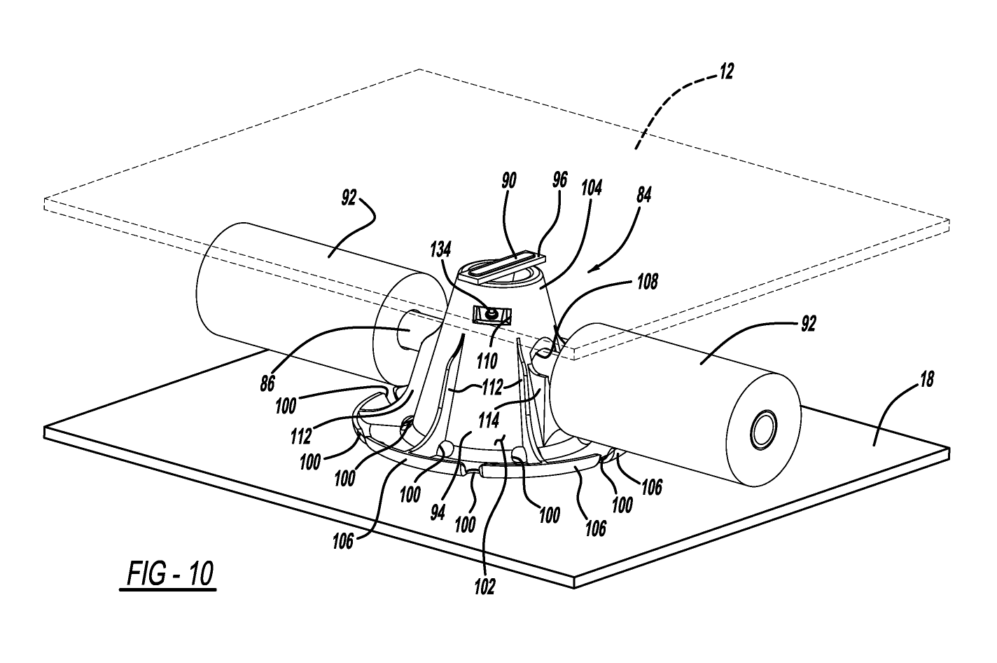

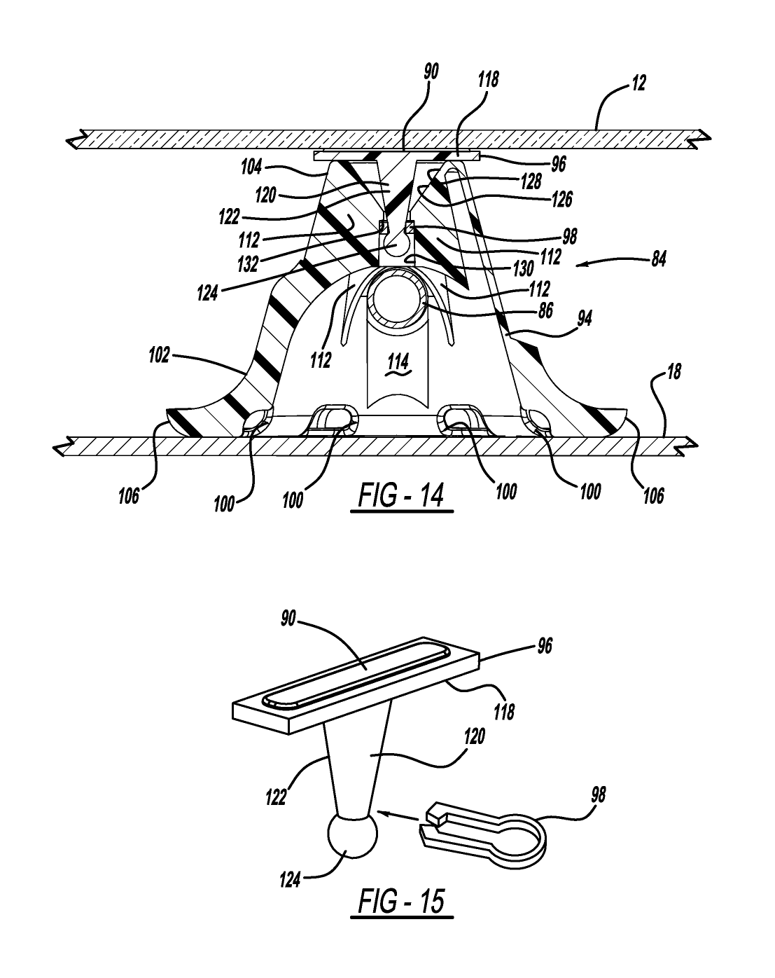

Referring now to FIGS. 10 through 15, each of the support assemblies 84 includes a stand 94, a bracket 96, and a coupler 98 (FIG. 15), such as a u-shaped clip, that secures the bracket 96 to the stand 94. The stand 94 may be formed from a plastic such as nylon via injection molding or vacuum forming. The bracket 96 may be formed from metal via injection molding or stamping. The stand 94 may be hollow, as shown, to reduce material costs. Holes 100 may be formed in the stand 94, as shown, to prevent the stand 94 from obstructing water flow on the roof 18.

As best shown in FIG. 10, the stand 94 has a base 102 and an apex 104 opposite from the base 102. The base 102 is wider than the apex 104 to distribute the load of the solar panel system 80 and thereby prevent leaks in the roof 18 caused by overloading the first section 20 of the roof 18. The apex 104 may be narrower than the base 102 to reduce material cost. The stand 94 may be a conical frustum, as shown, or the stand 94 may have another suitable shape, such as a square or rectangular frustum.

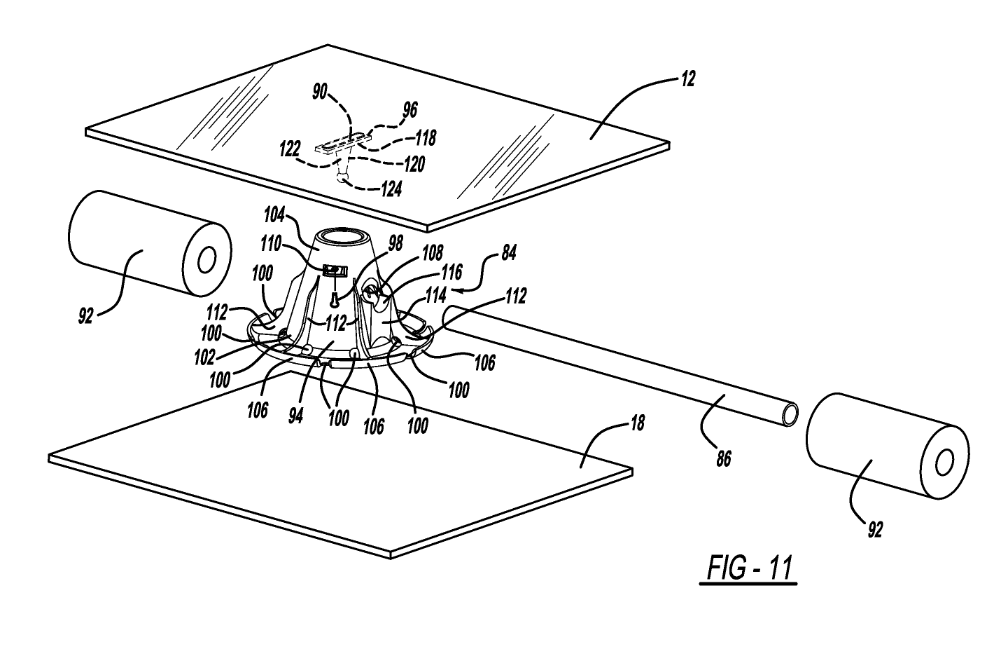

The stand 94 has edges 106 that are rounded to avoid piercing the roof 18 as the edges 106 contact the roof 18. The stand 94 defines holes 108 that extend horizontally through the stand 94. The pipes 86 are inserted through the holes 108 to secure the support assemblies 84 to the roof 18. The stand 94 also defines a hole 110 that provides access to insert the coupler 98 into the hollow interior of the stand 94. The stand 94 includes vertical ribs 112 disposed around the perimeter of the stand 94 that strengthen the stand 94, and ramped protrusions 114 that support the pipes 86. The protrusions 114 have surfaces 116 that are rounded to conform to the outer surfaces of the pipes 86 (FIG. 11).

As best shown in FIG. 11, the bracket 96 includes a pad 118 and a guide pin 120 that extends downward from the pad 118. The guide pin 120 includes a shank 122 and a head 124. The pad 118 may be rectangular, the shank 122 of the guide pin 120 may be conical, and the head 124 of the guide pin 120 may be spherical, as shown.

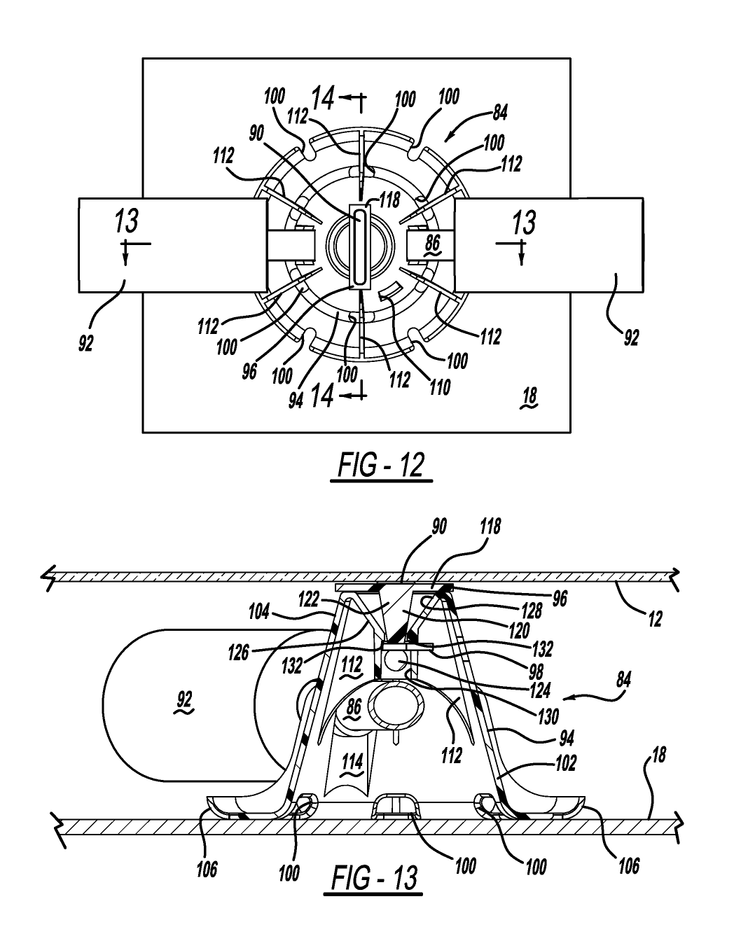

As best shown in FIGS. 12 through 15, the stand 94 includes a pin receptacle 126 that receives the guide pin 120. The pin receptacle 126 includes a first portion 128, a second portion 130, and a shoulder 132 between the first portion 128 and the second portion 130. The first portion 128 is tapered radially inward, or funnel shaped, to guide the head 124 of the guide pin 120 into the second portion 130. The second portion 130 has a circular cylinder shape. A hole 134 extends horizontally through the second portion 130 (FIG. 10).

The solar panel 12 is frameless. Thus, the bracket 96 may be preassembled to the solar panel 12 by applying the adhesive 90 to the top surface of the pad 118 and pressing the top surface of the pad 118 against the bottom or underside surface of the solar panel 12. In turn, the solar panel 12 may be lowered onto the stand 94 until the bottom surface of the pad 118 rests on the top surface of the stand 94 and the guide pin 120 is in the pin receptacle 126. The coupler 98 may then be inserted around the guide pin 120 between the head 124 of the guide pin 120 and the shoulder 132 of the pin receptacle 126 to secure that bracket 96 to the stand 94. The solar panel 12 may be disassembled for maintenance purposes by removing the coupler 98 from the guide pin 120 and lifting up on the solar panel 12.

Each of the support assemblies 84 may be modified to support two adjacent solar panels and thereby reduce the number of support assemblies 84 required to support the solar panels. In this regard, each of the support assemblies 84 may include two of the brackets 96, two of the couplers 98, and two of the pin receptacles 128. One of the brackets 96 may be preassembled to each of the two adjacent solar panels, and the solar panels may be individually lowered onto the support assemblies 84. The couplers 98 may then be inserted around the guide pins 120 on the brackets 96 to secure the brackets 96 to the stand 94.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A solar panel attachment system comprising:
a stand configured to rest on a roof of a building without piercing the roof;
an elongated member extending through the stand and configured to be fixed to the building; and
a bracket coupled to the stand and including a pad that is configured to support a solar panel.

2. The solar panel attachment system of claim 1, wherein the elongated member extends through the bracket.

3. The solar panel attachment system of claim 1, wherein the elongated member is a cable.

4. The solar panel attachment system of claim 1, wherein the stand has an apex and a base that is wider than the apex.

5. The solar panel attachment system of claim 4, wherein the stand has a square frustum shape.

6. The solar panel attachment system of claim 1, wherein the stand includes a permeated plastic.

7. The solar panel attachment system of claim 1, wherein the stand is molded over the bracket.

8. The solar panel attachment system of claim 1, wherein the bracket includes a flat portion and the pad is raised relative to the flat portion.

9. The solar panel attachment system of claim 8, wherein the pad is raised relative to the flat portion by an amount that prevents contact between the solar panel and the stand when the pad supports the solar panel.

10. The solar panel attachment system of claim 1, wherein the bracket is rectangular.

11. The solar panel attachment system of claim 1, wherein a bottom edge of the stand is rounded.

12. A solar panel system comprising:
a frameless solar panel;
the solar panel attachment system of claim 1; and
an adhesive that fixes the bracket to the frameless solar panel.

13. A solar panel attachment system comprising:
a bracket including a pad and a guide pin, the pad being configured to support a solar panel, the guide pin extending from the pad;
a stand including a pin receptacle configured to receive the guide pin; and
a coupler configured to releasably couple the bracket to the stand.

14. The solar panel attachment system of claim 13, wherein the guide pin includes a head and the pin receptacle includes a shoulder.

15. The solar panel attachment system of claim 14, wherein the coupler retains the guide pin in the pin receptacle when the coupler is disposed between the head of the guide pin and the shoulder of the pin receptacle.

16. The solar panel attachment system of claim 13, wherein the coupler includes a u-shaped clip.

17. The solar panel attachment system of claim 13, further comprising an elongated member extending through the stand and configured to be fixed to a building.

18. The solar panel attachment system of claim 17, wherein the elongated member is a pipe.

19. The solar panel attachment system of claim 17, further comprising a weight disposed about the elongated member.

20. The solar panel attachment system of claim 19, wherein the weight is cylindrical.

21. The solar panel attachment system of claim 19, wherein the weight is elevated relative to a roof of the building when the stand is resting on the roof.

22. The solar panel attachment system of claim 13, wherein holes extend through the stand to allow water flow through the stand when the stand is resting on a roof of a building.

23. The solar panel attachment system of claim 13, wherein the stand includes vertical ribs disposed about the perimeter of the stand.

24. A solar panel system, comprising:
a frameless solar panel;
the solar panel attachment system of claim 13; and
an adhesive that fixes the bracket to the frameless solar panel.

25. A solar panel attachment system, comprising:
a bracket having a rectangular pad and a guide pin extending from the rectangular pad, the guide pin including a conical shank and a spherical head; and
a conical stand having a base and an apex that is narrower than the base, the conical stand having a hollow interior and including a pin receptacle, the pin receptacle extending into the hollow interior of the conical stand and having a funnel-shaped portion and a cylindrical portion, the funnel-shaped portion being tapered radially inward from a first end of the funnel-shaped portion adjoining the apex to a second end of the funnel-shaped portion opposite from the first end.

26. The solar panel attachment system of claim 25, further comprising a cylindrical member configured to extend through the stand.

27. The solar panel attachment system of claim 26, wherein the cylindrical member is hollow.

28. The solar panel attachment system of claim 26, further comprising a cylindrical weight configured to slide over the cylindrical member.

29. The solar panel attachment system of claim 26, wherein the conical stand includes a ramped protrusion having a rounded top surface that conforms to an outer surface of the cylindrical member.

30. A method of attaching a solar panel to a building, the method comprising:
(a) fixing an elongated member to the building;
(b) inserting the elongated member through a stand;
(c) preassembling a bracket to a frameless solar panel using an adhesive; and
(d) coupling the bracket to the stand.

31. The method of claim 30, further comprising coupling the bracket to the stand using a snap-fit connection.

32. The method of claim 30, further comprising coupling the bracket to the stand using a tongue-and-groove connection.

33. The method of claim 30, further comprising lowering the frameless solar panel onto the stand to engage a guide pin on the bracket with a pin receptacle on the stand.

34. The method of claim 33, further comprising engaging the guide pin with a coupler to retain the guide pin in the pin receptacle.
